(19) United States
(12) Patent Application Publication
(10) Pub. No.: US 2026/0068210 A1
(43) Pub. Date: Mar. 5, 2026

(54) SEMICONDUCTOR DEVICE AND MANUFACTURING METHOD THEREOF

(71) Applicant: TAIWAN SEMICONDUCTOR MANUFACTURING COMPANY LTD., HSINCHU (TW)

(72) Inventors: ZHI WEI HUANG, HSINCHU CITY (TW); SHIH-PANG CHANG, HSINCHU COUNTY (TW); RU-YI SU, YUNLIN COUNTY (TW); CHUN-LIN TSAI, HSIN-CHU (TW); CHENG JU TSAI, HSINCHU CITY (TW); CHING YU CHEN, HSINCHU COUNTY (TW)

(21) Appl. No.: 18/815,883

(22) Filed: Aug. 27, 2024

(51) Int. Cl. H01L 29/778; H01L 21/02; H01L 29/20; H01L 29/66

(52) U.S. Cl. CPC H10D 30/4755; H10D 30/015; H10D 62/8503

(57) ABSTRACT

The present disclosure provides a gallium nitride-based semiconductor device. The semiconductor device includes: a substrate; an epitaxial layer on the substrate; a first aluminum-containing layer on the epitaxial layer; a source terminal, a drain terminal, and a gate terminal on the first aluminum-containing layer, wherein the gate terminal is between the source terminal and the drain terminal; a second aluminum-containing layer over the first aluminum-containing layer and between the gate terminal and the drain terminal; and a third aluminum-containing layer over the second aluminum-containing layer. The first aluminum-containing layer has a first concentration of aluminum, the second aluminum-containing layer has a second concentration of aluminum, and the third aluminum-containing layer has a third concentration of aluminum. The second concentration is substantially greater than the first concentration, and the second concentration is substantially greater than the third concentration.

### BACKGROUND

The semiconductor integrated circuit (IC) industry has experienced exponential growth. Technological advances in IC materials and design have produced generations of ICs where each generation has smaller and more complex circuits than the previous generation.

As technological standards advance, there is an ever-increasing consumer demand for semiconductor ICs that occupy less space, consume less power, and perform higher-quality computing at greater speeds. As a result, there remains a need to develop methods for manufacturing improved semiconductor devices.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic cross-sectional view of a first semiconductor device, in accordance with some embodiments of the present disclosure.

FIG. 2 is a schematic cross-sectional view of a second semiconductor device, in accordance with various embodiments of the present disclosure.

FIG. 3 is a schematic cross-sectional view of a third semiconductor device, in accordance with various embodiments of the present disclosure.

FIG. 4 is a schematic cross-sectional view of a fourth semiconductor device, in accordance with various embodiments of the present disclosure.

FIG. 5 is a schematic cross-sectional view of a fifth semiconductor device, in accordance with various embodiments of the present disclosure.

FIG. 6 is a flow diagram showing a method for forming a semiconductor device, in accordance with some embodiments of the present disclosure.

FIGS. 7 to 16 are schematic cross-sectional views illustrating sequential operations of the method in FIG. 6, in accordance with some embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In some embodiments, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass orientations of the device in use or operation in some embodiments different from the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range which can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

In semiconductor technology, gallium nitride (GaN), as part of a generation of wide band gap semiconductor materials, has characteristics of large band gap, high breakdown voltage, and ability to provide a two-dimensional electron gas having large electron velocities at high concentrations. Gallium nitride is used to form various integrated circuit devices, such as high-power field-effect transistors, metal-insulator semiconductor field-effect transistors (MISFETs), high-frequency transistors, and high-electron-mobility transistors (HEMTs). The present disclosure provides a gallium nitride-based semiconductor device and a manufacturing method thereof.

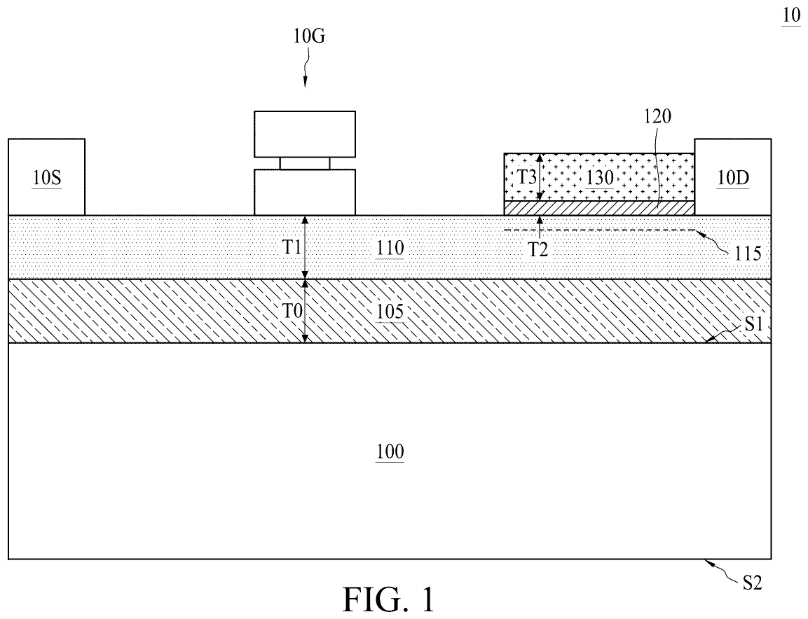

FIG. 1 is a schematic cross-sectional view of a semiconductor device 10. In some embodiments, the semiconductor device 10 is a high-electron-mobility transistor (HEMT) or a portion of a high-electron-mobility transistor. In some embodiments, the semiconductor device 10 includes an epitaxial layer 105 disposed on a semiconductor substrate 100. A first aluminum-containing semiconductive layer 110, a second aluminum-containing semiconductive layer 120, and a third aluminum-containing semiconductive layer 130 are formed over the epitaxial layer 105.

In some embodiments, the semiconductor substrate 100 is made of, for example, silicon; a compound semiconductor, such as silicon carbide, indium arsenide, or indium phosphide; or an alloy semiconductor, such as silicon germanium carbide, gallium arsenic phosphide, or gallium indium phosphide. In other embodiments, the semiconductor substrate 100 is a sapphire substrate. The semiconductor substrate 100 may be a bulk substrate formed of a bulk material, or a composite substrate including a plurality of layers that are formed of different materials. The semiconductor substrate 100 has a first surface S1 and a second surface S2 opposite to the first surface S1.

The epitaxial layer 105 is formed on the first surface S1 of the semiconductor substrate 100. The epitaxial layer 105 may be a compound layer formed from III and V groups in the periodic table of elements. In some embodiments, the epitaxial layer 105 is gallium nitride (GaN). The epitaxial layer 105 may be referred to as a GaN layer. In some embodiments, the epitaxial layer 105 has a thickness T0 in a range from about 0.1 micrometer (μm) to about 20 μm. The epitaxial layer 105 may be used to dissipate heat and reduce thermal resistance of the semiconductor substrate 100.

The first aluminum-containing semiconductive layer 110 is disposed on the epitaxial layer 105. In some embodiments, a gate terminal (structure) 10G, a source terminal (structure) 10S and a drain terminal (structure) 10D are disposed on and electrically connected to the first aluminum-containing semiconductive layer 110. The source terminal 10S and the drain terminal 10D may refer to a source or a drain, individually or collectively dependent upon the context. The gate terminal 10G is disposed between the source terminal 10S and the drain terminal 10D. In some embodiments, the gate terminal 10G is a stack structure including a doped GaN layer, a dielectric layer or a piezoelectric layer, and a metal layer, but the present disclosure is not limited thereto. According to different embodiments, the gate terminal 10G may have different compositions and/or configurations. The source terminal 10S and the drain terminal 10D are made of metals and may be referred to as ohmic contacts.

The second aluminum-containing semiconductive layer 120 is disposed on a portion of the first aluminum-containing semiconductive layer 110. In some embodiments, the second aluminum-containing semiconductive layer 120 is disposed between the gate terminal 10G and the drain terminal 10D. The second aluminum-containing semiconductive layer 120 may be in contact with or separated from the drain terminal 10D. The third aluminum-containing semiconductive layer 130 is disposed on the second aluminum-containing semiconductive layer 120. In some embodiments, the third aluminum-containing semiconductive layer 130 is disposed between the gate terminal 10G and the drain terminal 10D. The third aluminum-containing semiconductive layer 130 may be in contact with or separated from the drain terminal 10D.

In some embodiments, the third aluminum-containing semiconductive layer 130 completely covers the second aluminum-containing semiconductive layer 120. That is, the third aluminum-containing semiconductive layer 130 covers an entirety of the second aluminum-containing semiconductive layer 120. In such embodiments, a sidewall of the third aluminum-containing semiconductive layer 130 is substantially aligned with a sidewall of the second aluminum-containing semiconductive layer 120. In other embodiments, the third aluminum-containing semiconductive layer 130 covers a portion of the second aluminum-containing semiconductive layer 120. In such embodiments, the third aluminum-containing semiconductive layer 130 exposes another portion of the second aluminum-containing semiconductive layer 120.

An interface is present between the second aluminum-containing semiconductive layer 120 and the first aluminum-containing semiconductive layer 110, and another interface is present between the third aluminum-containing semiconductive layer 130 and the second aluminum-containing semiconductive layer 120. Such interfaces can be observed using a transmission electron microscope (TEM) technique.

The first, second and third aluminum-containing semiconductive layers 110, 120 and 130 are respectively compound layers formed from III and V groups in the periodic table of elements, and may be referred to as III-V compound layers. In some embodiments, the first, second and third aluminum-containing semiconductive layers 110, 120 and 130 respectively include aluminum gallium nitride (AlₓGa₁₋ₓN, in which 0<x<1). In some embodiments, the first, second and third aluminum-containing semiconductive layers 110, 120 and 130 are different from each other in composition. The first aluminum-containing semiconductive layer 110 has a first concentration or atomic ratio of aluminum (Al), the second aluminum-containing semiconductive layer 120 has a second concentration or atomic ratio of aluminum, and the third aluminum-containing semiconductive layer 130 has a third concentration or atomic ratio of aluminum. In some embodiments, the concentration or atomic ratio of aluminum of a certain layer is defined as its amount of aluminum divided by an overall amount of all elements in such layer. The concentration or atomic ratio of a specific element may be determined using an Energy Dispersive X-ray (EDX) analysis. In some embodiments, the second concentration is substantially greater than the first concentration, and the second concentration is substantially greater than the third concentration. In some embodiments, the first concentration is substantially equal to the third concentration.

The first aluminum-containing semiconductive layer 110 has a first thickness T1, the second aluminum-containing semiconductive layer 120 has a second thickness T2, and the third aluminum-containing semiconductive layer 130 has a third thickness T3. In some embodiments, the first thickness T1 is substantially greater than the second thickness T2, and the third thickness T3 is substantially greater than the second thickness T2. In some embodiments, the first thickness T1 or the third thickness T3 is in a range from about 0.1 nanometer (nm) to about 100 nm.

The epitaxial layer 105 and the first, second and third aluminum-containing semiconductive layers 110, 120 and 130 over the semiconductor substrate 100 have different materials or compositions. Thus, such layers may have different band gaps. A band gap refers to an energy range in a solid where no electronic states exist. The first aluminum-containing semiconductive layer 110 has a first band gap, the second aluminum-containing semiconductive layer 120 has a second band gap, and the third aluminum-containing semiconductive layer 130 has a third band gap. In some embodiments, the first band gap is different from the second band gap. In some embodiments, the first band gap is substantially equal to the third band gap. In some embodiments, a band gap discontinuity between the first aluminum-containing semiconductive layer 110 and the second aluminum-containing semiconductive layer 120 creates a thin layer 115 of highly mobile electrons within the first aluminum-containing semiconductive layer 110. The thin layer 115 contributes to a conductive two-dimensional electron gas (2DEG) region near a junction of the first aluminum-containing semiconductive layer 110 and the second aluminum-containing semiconductive layer 120. The thin layer 115, which may be referred to as a 2DEG layer 115, allows charges to flow through the first aluminum-containing semiconductive layer 110 when the semiconductor device 10 is in operation. The gate terminal 10G is configured for voltage bias and electrical coupling with the 2DEG layer 115 (i.e., a channel below the gate terminal 10G). In some embodiments, an on-state resistance of the semiconductor device 10 is substantially less than 1.3 ohm (Ω).

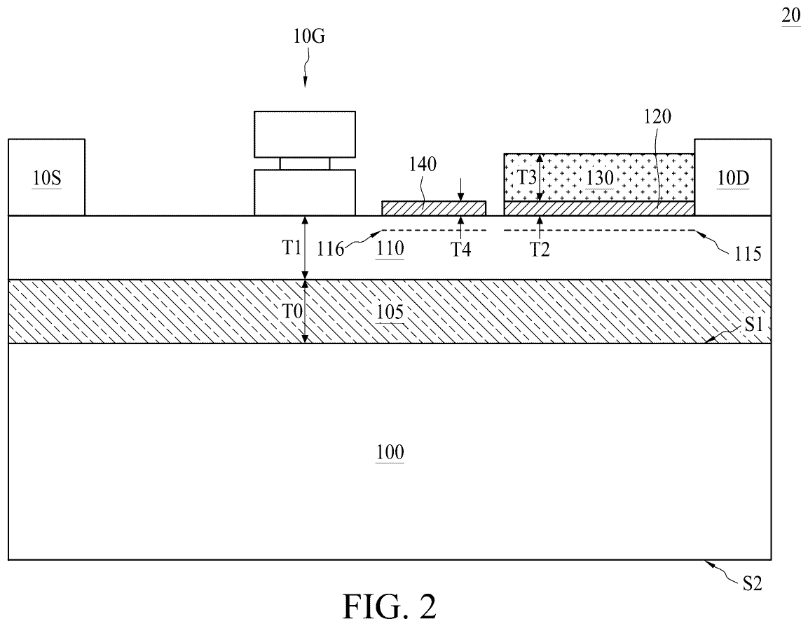

FIG. 2 is a schematic cross-sectional view of a semiconductor device 20 according to various embodiments of the present disclosure. The semiconductor device 20 is similar to the semiconductor device 10 in FIG. 1, except that the semiconductor device 20 includes a fourth aluminum-containing semiconductive layer 140 disposed over the first aluminum-containing semiconductive layer 110 and adjacent to the gate terminal 10G. In some embodiments, the fourth aluminum-containing semiconductive layer 140 is disposed between the gate terminal 10G and the second aluminum-containing semiconductive layer 120. In some embodiments, the fourth aluminum-containing semiconductive layer 140 is separated from the gate terminal 10G and the second aluminum-containing semiconductive layer 120, as shown in FIG. 2. In other embodiments, the fourth aluminum-containing semiconductive layer 140 is in contact with the gate terminal 10G or the second aluminum-containing semiconductive layer 120.

The fourth aluminum-containing semiconductive layer 140 has a fourth thickness T4. In some embodiments, the first thickness T1 is substantially greater than the fourth thickness T4, and the third thickness T3 is substantially greater than the fourth thickness T4. In some embodiments, the fourth thickness T4 is substantially equal to the second thickness T2.

The fourth aluminum-containing semiconductive layer 140 has a fourth concentration or atomic ratio of aluminum. In some embodiments, the fourth concentration is substantially greater than the first concentration, and the fourth concentration is substantially greater than the third concentration. In some embodiments, the fourth concentration is substantially equal to the second concentration. In other embodiments, the fourth concentration is substantially greater than the second concentration.

The second and fourth aluminum-containing semiconductive layers 120 and 140 cover portions of the first aluminum-containing semiconductive layer 110. In some embodiments, a band gap discontinuity between the first aluminum-containing semiconductive layer 110 and the fourth aluminum-containing semiconductive layer 140 creates a 2DEG layer 116 of highly mobile electrons near a junction of the first aluminum-containing semiconductive layer 110 and the fourth aluminum-containing semiconductive layer 140. The semiconductor device 20 includes the 2DEG layers 115 and 116 within the first aluminum-containing semiconductive layer 110. In some embodiments, the 2DEG layers 115 and 116 are separated from each other. The 2DEG layers 115 and 116 allow charges to flow through the first aluminum-containing semiconductive layer 110 when the semiconductor device 20 is in operation. The gate terminal 10G is configured for voltage bias and electrical coupling with the 2DEG layers 115 and 116. In some embodiments, an on-state resistance of the semiconductor device 20 is substantially less than 1.3Ω.

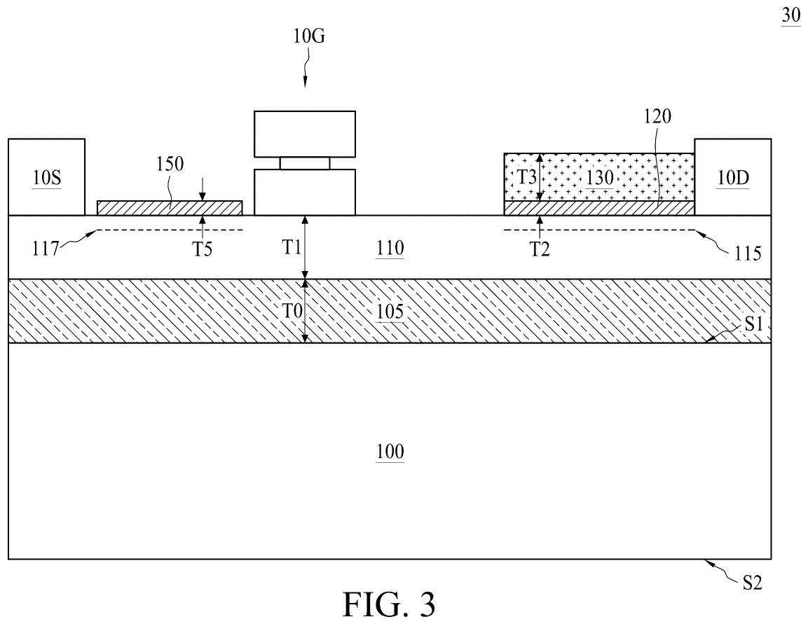

FIG. 3 is a schematic cross-sectional view of a semiconductor device 30 according to various embodiments of the present disclosure. The semiconductor device 30 is similar to the semiconductor device 10 in FIG. 1, except that the semiconductor device 30 includes a fifth aluminum-containing semiconductive layer 150 disposed over the first aluminum-containing semiconductive layer 110 and adjacent to the gate terminal 10G. In some embodiments, the fifth aluminum-containing semiconductive layer 150 is disposed between the gate terminal 10G and the source terminal 10S. In some embodiments, the fifth aluminum-containing semiconductive layer 150 is separated from the gate terminal 10G and the source terminal 10S, as shown in FIG. 3. In other embodiments, the fifth aluminum-containing semiconductive layer 150 is in contact with the gate terminal 10G or the source terminal 10S.

The fifth aluminum-containing semiconductive layer 150 has a fifth thickness T5. In some embodiments, the first thickness T1 is substantially greater than the fifth thickness T5, and the third thickness T3 is substantially greater than the fifth thickness T5. In some embodiments, the fifth thickness T5 is substantially equal to the second thickness T2.

The fifth aluminum-containing semiconductive layer 150 has a fifth concentration or atomic ratio of aluminum. In some embodiments, the fifth concentration is substantially greater than the first concentration, and the fifth concentration is substantially greater than the third concentration. In some embodiments, the fifth concentration is substantially equal to the second concentration. In other embodiments, the fifth concentration is substantially greater than the second concentration.

The second and fifth aluminum-containing semiconductive layers 120 and 150 cover portions of the first aluminum-containing semiconductive layer 110. In some embodiments, a band gap discontinuity between the first aluminum-containing semiconductive layer 110 and the fifth aluminum-containing semiconductive layer 150 creates a 2DEG layer 117 of highly mobile electrons near a junction of the first aluminum-containing semiconductive layer 110 and the fifth aluminum-containing semiconductive layer 150. The semiconductor device 30 includes the 2DEG layers 115 and 117 within the first aluminum-containing semiconductive layer 110. In some embodiments, the 2DEG layers 115 and 117 are separated from each other. The 2DEG layers 115 and 117 allow charges to flow through the first aluminum-containing semiconductive layer 110 when the semiconductor device 30 is in operation. The gate terminal 10G is configured for voltage bias and electrical coupling with the 2DEG layers 115 and 117. In some embodiments, an on-state resistance of the semiconductor device 30 is substantially less than 1.3Ω.

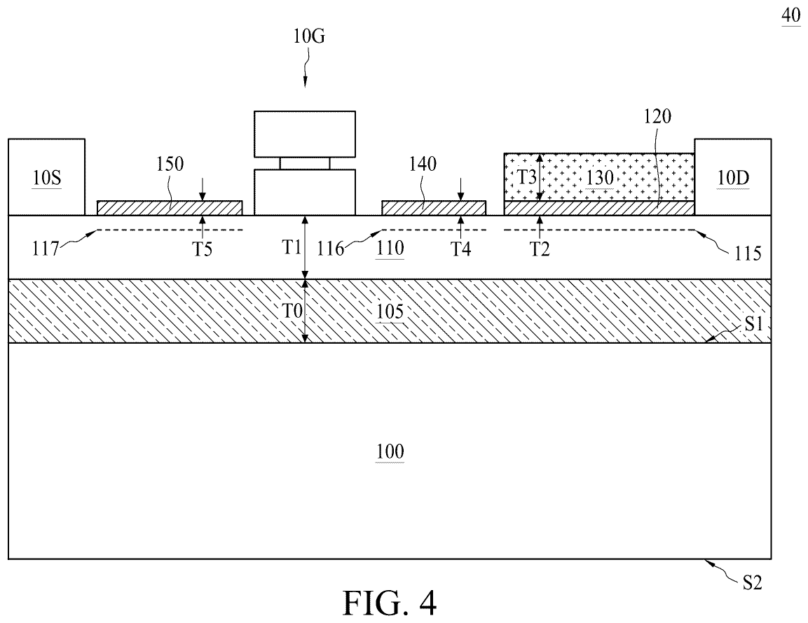

FIG. 4 is a schematic cross-sectional view of a semiconductor device 40 according to various embodiments of the present disclosure. The semiconductor device 40 is similar to the semiconductor device 20 in FIG. 2 or the semiconductor device 30 in FIG. 3, except that the semiconductor device 40 includes both the fourth aluminum-containing semiconductive layer 140 and the fifth aluminum-containing semiconductive layer 150 disposed over the first aluminum-containing semiconductive layer 110 and at two sides of the gate terminal 10G. The semiconductor device 40 includes the 2DEG layers 115, 116 and 117 within the first aluminum-containing semiconductive layer 110. In some embodiments, the 2DEG layers 115, 116 and 117 are separated from each other. The 2DEG layers 115, 116 and 117 allow charges to flow through the first aluminum-containing semiconductive layer 110 when the semiconductor device 40 is in operation. The gate terminal 10G is configured for voltage bias and electrical coupling with the 2DEG layers 115, 116 and 117. In some embodiments, an on-state resistance of the semiconductor device 40 is substantially less than 1.3Ω.

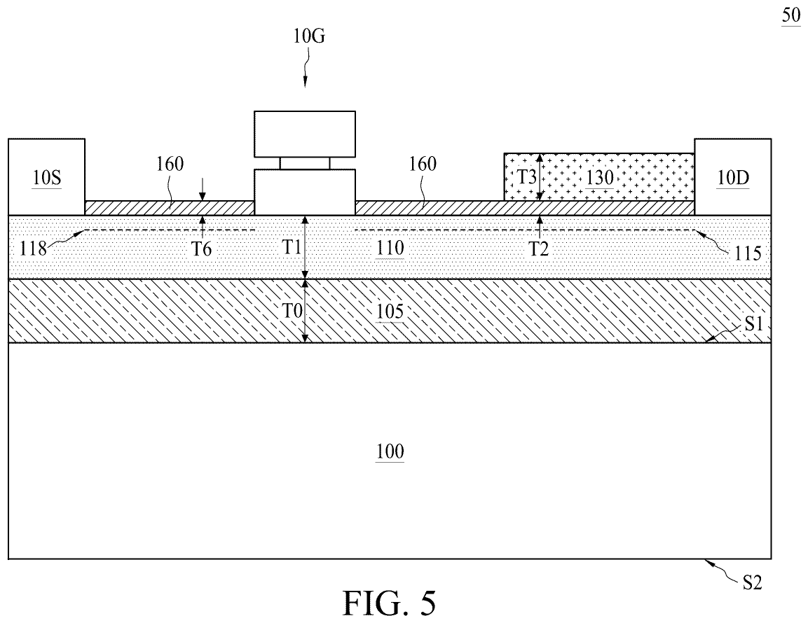

FIG. 5 is a schematic cross-sectional view of a semiconductor device 50 according to various embodiments of the present disclosure. The semiconductor device 50 is similar to the semiconductor device 40 in FIG. 4, except that in the semiconductor device 50, exposed surfaces of the first aluminum-containing semiconductive layer 110 are completely covered by a sixth aluminum-containing semiconductive layer 160. In some embodiments, the sixth aluminum-containing semiconductive layer 160 is disposed between the source terminal 10S and the drain terminal 10D. A portion of the sixth aluminum-containing semiconductive layer 160 is disposed between the source terminal 10S and the gate terminal 10G, and another portion of the sixth aluminum-containing semiconductive layer 160 is disposed between the drain terminal 10D and the gate terminal 10G. In some embodiments, the gate terminal 10G is surrounded by the sixth aluminum-containing semiconductive layer 160. In some embodiments, the sixth aluminum-containing semiconductive layer 160 is in contact with the source terminal 10S, the drain terminal 10D and the gate terminal 10G.

The sixth aluminum-containing semiconductive layer 160 has a sixth thickness T6. In some embodiments, the first thickness T1 is substantially greater than the sixth thickness T6, and the third thickness T3 is substantially greater than the sixth thickness T6.

The sixth aluminum-containing semiconductive layer 160 has a sixth concentration or atomic ratio of aluminum. In some embodiments, the sixth concentration is substantially greater than the first concentration, and the sixth concentration is substantially greater than the third concentration.

The sixth aluminum-containing semiconductive layer 160 covers portions of the first aluminum-containing semiconductive layer 110. In some embodiments, a band gap discontinuity between the first aluminum-containing semiconductive layer 110 and the sixth aluminum-containing semiconductive layer 160 creates a 2DEG layer 118 of highly mobile electrons near a junction of the first aluminum-containing semiconductive layer 110 and the sixth aluminum-containing semiconductive layer 160. The semiconductor device 50 includes the 2DEG layer 118 within the first aluminum-containing semiconductive layer 110. The 2DEG layer 118 allows charges to flow through the first aluminum-containing semiconductive layer 110 when the semiconductor device 50 is in operation. The gate terminal 10G is configured for voltage bias and electrical coupling with the 2DEG layer 118. In some embodiments, an on-state resistance of the semiconductor device 50 is substantially less than 1.3 Ω.

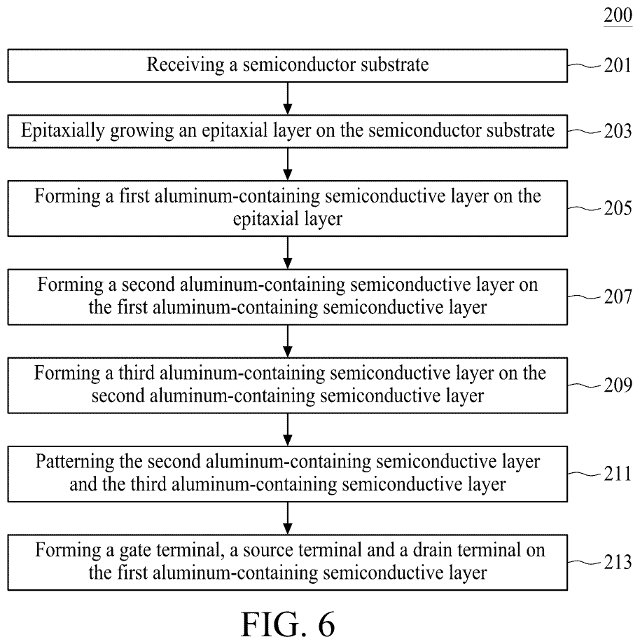

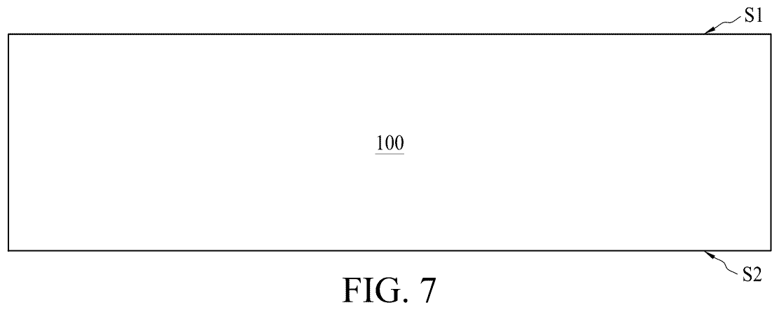

FIG. 6 is a flow diagram showing a method 200 for forming a semiconductor device 10. FIGS. 7 to 16 are schematic cross-sectional views illustrating sequential operations of the method 200 in FIG. 6. The method 200 is merely an example, and is not intended to limit the scope of the present disclosure. Additional operations can be provided before, during, and after the method 200, and some operations described can be replaced, eliminated, or moved around for additional embodiments of the method 200.

In operation 201 of the method 200, a semiconductor substrate 100 is received, as shown in FIG. 7. The semiconductor substrate 100 is made of, for example, silicon; a compound semiconductor, such as silicon carbide, indium arsenide, or indium phosphide; or an alloy semiconductor, such as silicon germanium carbide, gallium arsenic phosphide, or gallium indium phosphide. The semiconductor substrate 100 may be a sapphire substrate, a bulk substrate or a composite substrate including a plurality of layers that are formed of different materials. The semiconductor substrate 100 has a first surface S1 and a second surface S2 opposite to the first surface S1.

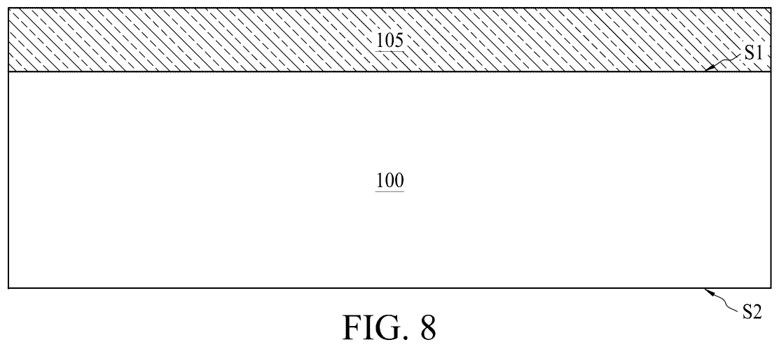

In operation 203 of the method 200, an epitaxial layer 105 is epitaxially grown on the semiconductor substrate 100, as shown in FIG. 8. In some embodiments, the epitaxial layer 105 is formed on the first surface S1 of the semiconductor substrate 100 using metal organic vapor phase epitaxy (MOVPE) or another suitable epitaxial method. The epitaxial layer 105 may include a single layer or a plurality of layers. The epitaxial layer 105 may be a compound layer formed from III and V groups in the periodic table of elements. In some embodiments, the epitaxial layer 105 includes gallium nitride (GaN). The epitaxial layer 105 may be referred to as a GaN layer. In some embodiments, the epitaxial layer 105 has a thickness between about 0.1 μm and about 20 μm.

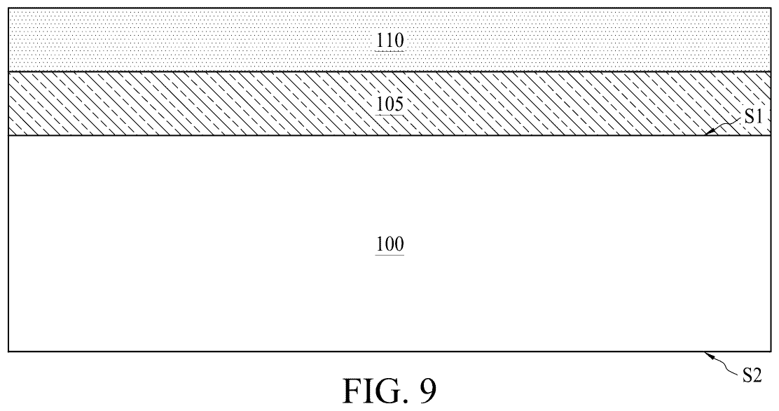

In operation 205 of the method 200, a first aluminum-containing semiconductive layer 110 is formed on the epitaxial layer 105, as shown in FIG. 9. In some embodiments, the first aluminum-containing semiconductive layer 110 is formed using a chemical vapor deposition (CVD) operation such as metal organic chemical vapor deposition (MOCVD), but the present disclosure is not limited thereto. In other embodiments, the first aluminum-containing semiconductive layer 110 is formed using a vapor phase epitaxy operation such as metal organic vapor phase epitaxy (MOVPE). In some embodiments, the first aluminum-containing semiconductive layer 110 is made of aluminum gallium nitride (AlₓGa₁₋ₓN, in which 0<x<1). The first aluminum-containing semiconductive layer 110 may be grown using an aluminum-containing precursor, a gallium-containing precursor and a nitrogen-containing precursor. The aluminum-containing precursor may include trimethylaluminum (TMA), triethylaluminum (TEA), or other suitable aluminum-containing chemicals. The gallium-containing precursor may include trimethylgallium (TMG), triethylgallium (TEG), or other suitable gallium-containing chemicals. The nitrogen-containing precursor may include ammonia (NH₃), tertiarybutylamine (TBAm), phenyl hydrazine, or other suitable nitrogen-containing chemicals. The first aluminum-containing semiconductive layer 110 has a thickness between about 0.1 nanometer and about 100 nm.

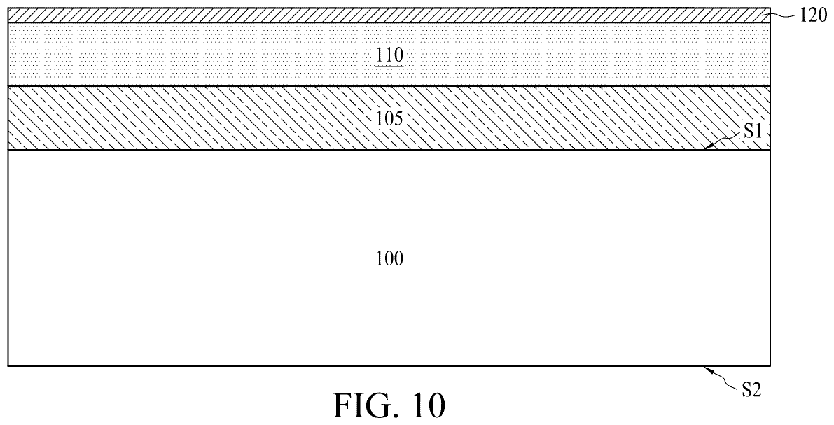

In operation 207 of the method 200, a second aluminum-containing semiconductive layer 120 is formed on the first aluminum-containing semiconductive layer 110, as shown in FIG. 10. The second aluminum-containing semiconductive layer 120 may be formed using a method similar to that used for forming the first aluminum-containing semiconductive layer 110. In some embodiments, the second aluminum-containing semiconductive layer 120 is made of aluminum gallium nitride (AlₓGa₁₋ₓN, in which 0<x<1). In some embodiments, the second aluminum-containing semiconductive layer 120 is grown in a process chamber same as that used for forming the first aluminum-containing semiconductive layer 110. In such embodiments, the precursors for forming the first aluminum-containing semiconductive layer 110 and the second aluminum-containing semiconductive layer 120 are substantially the same. However, in some embodiments, in the formation of the second aluminum-containing semiconductive layer 120, a proportion of the aluminum-containing precursor among all precursors introduced into the process chamber is increased. That is, an aluminum composition in the precursors for forming the second aluminum-containing semiconductive layer 120 is greater than an aluminum composition in the precursors for forming the first aluminum-containing semiconductive layer 110. An interface exists between the second aluminum-containing semiconductive layer 120 and the first aluminum-containing semiconductive layer 110. Such interface can be observed using a TEM technique. A thickness of the second aluminum-containing semiconductive layer 120 is less than the thickness of the first aluminum-containing semiconductive layer 110.

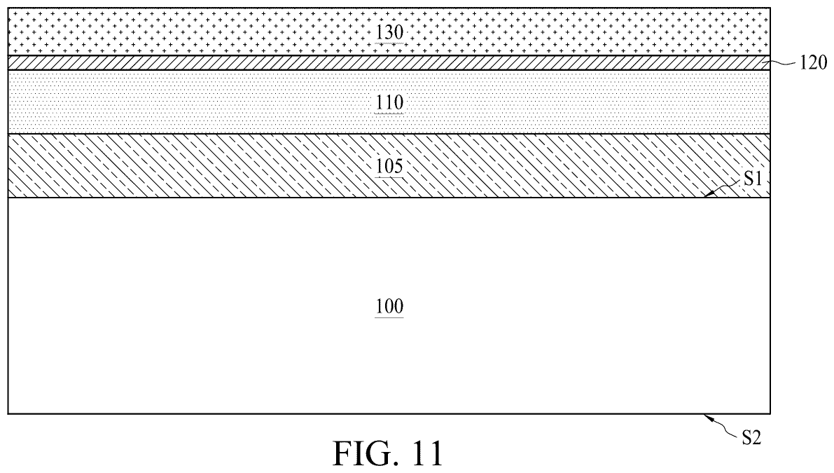

In operation 209 of the method 200, a third aluminum-containing semiconductive layer 130 is formed on the second aluminum-containing semiconductive layer 120, as shown in FIG. 11. The third aluminum-containing semiconductive layer 130 may be formed using a method similar to that used for forming the first aluminum-containing semiconductive layer 110. In some embodiments, the third aluminum-containing semiconductive layer 130 is made of aluminum gallium nitride (AlₓGa₁₋ₓN, in which 0<x<1). In some embodiments, the third aluminum-containing semiconductive layer 130 is grown in the same process chamber used for forming the first and second aluminum-containing semiconductive layers 110 and 120. In some embodiments, aluminum, gallium and nitrogen compositions in the precursors for forming the first aluminum-containing semiconductive layer 110 and the third aluminum-containing semiconductive layer 130 are substantially the same.

An interface exists between the third aluminum-containing semiconductive layer 130 and the second aluminum-containing semiconductive layer 120. Such interface can be observed using a TEM technique. The third aluminum-containing semiconductive layer 130 has a thickness between about 0.1 nanometer and about 100 nm.

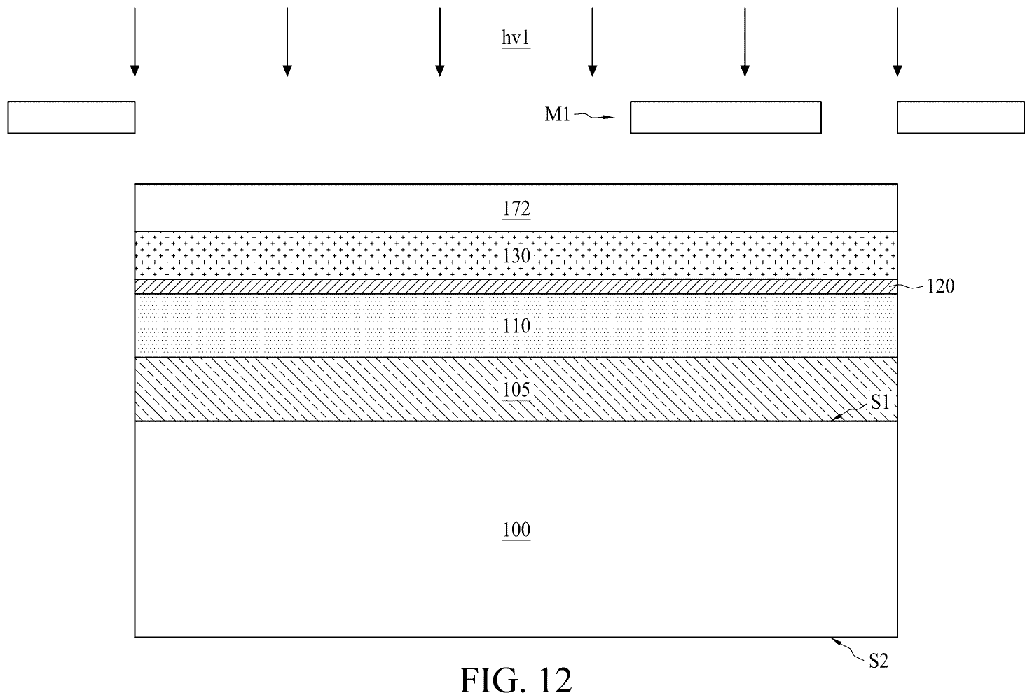

In operation 211 of the method 200, the second aluminum-containing semiconductive layer 120 and the third aluminum-containing semiconductive layer 130 are patterned, as shown in FIGS. 12 to 15. Referring to FIG. 12, a photoresist layer 172 is deposited on the third aluminum-containing semiconductive layer 130. Subsequently, the photoresist layer 172 is exposed to a radiation hv1 through a photomask M1. In some embodiments, a layout of the photomask M1 is used to control which portions of the second aluminum-containing semiconductive layer 120 and the third aluminum-containing semiconductive layer 130 are removed.

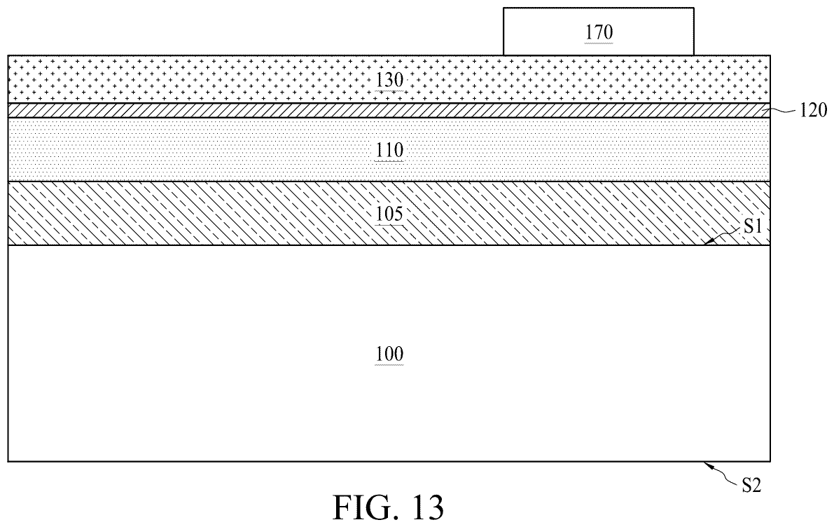

Referring to FIG. 13, exposed portions of the photoresist layer 172 are developed, thus forming a photoresist pattern 170. The photoresist pattern 170 covers a portion of the third aluminum-containing semiconductive layer 130.

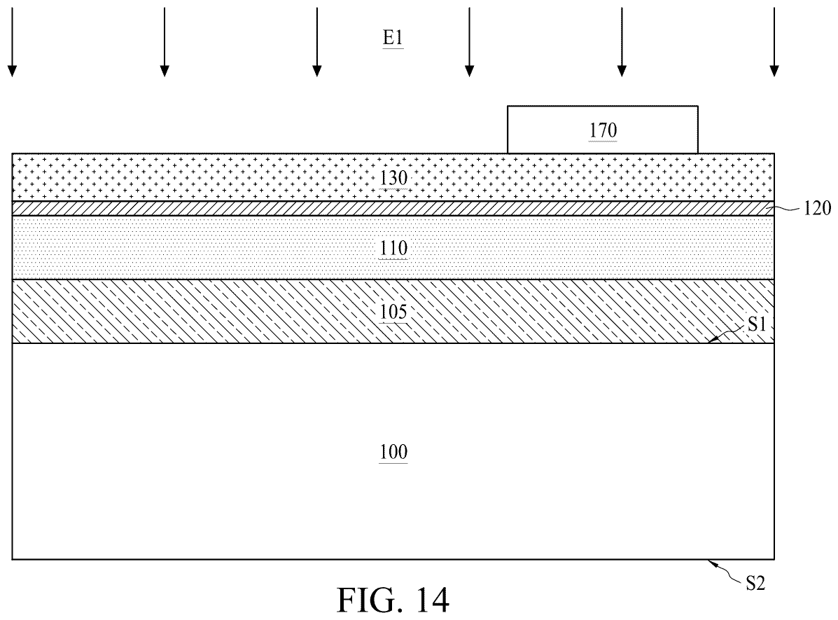

Referring to FIG. 14, an etching operation E1 is performed on the third aluminum-containing semiconductive layer 130 and the second aluminum-containing semiconductive layer 120. An etching rate or etching time of the etching operation E1 may be controlled to remove the second and third aluminum-containing semiconductive layers 120 and 130 not protected by the photoresist pattern 170 without etching the first aluminum-containing semiconductive layer 110.

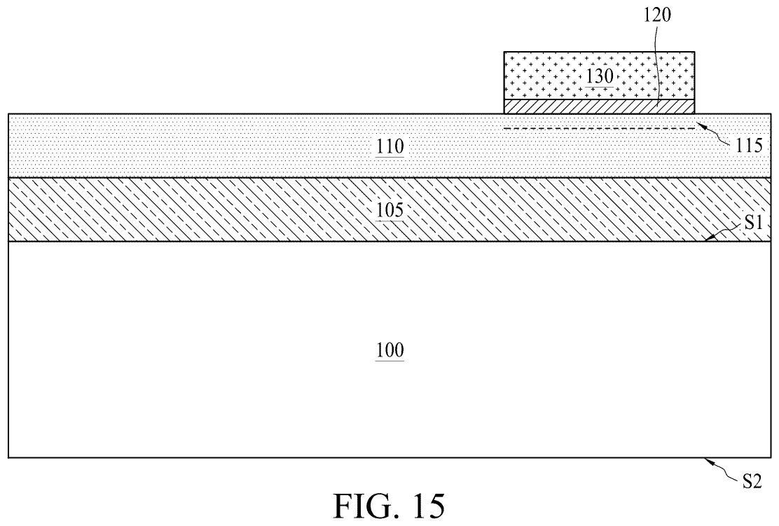

Referring to FIG. 15, after the etching operation E1 is performed, the photoresist pattern 170 is removed. The second aluminum-containing semiconductive layer 120 remains on a portion of the first aluminum-containing semiconductive layer 110. A sidewall of the third aluminum-containing semiconductive layer 130 is substantially aligned with a sidewall of the second aluminum-containing semiconductive layer 120.

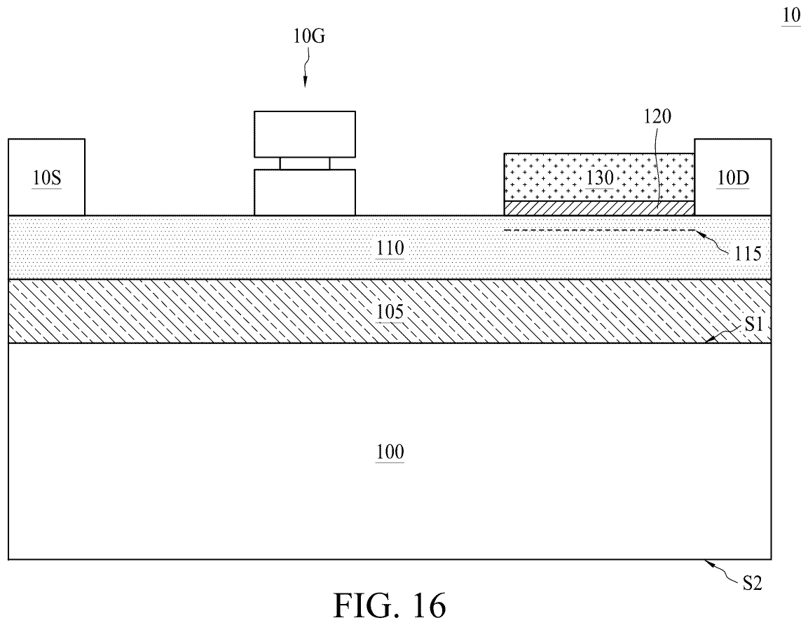

In operation 213 of the method 200, a gate terminal 10G, a source terminal 10S, and a drain terminal 10D are formed on the first aluminum-containing containing semiconductive layer 110, as shown in FIG. 16. A method for forming the gate terminal 10G, the source terminal 10S and the drain terminal 10D may include multiple processes including photolithography, etching, deposition, or the like. An order for forming the gate terminal 10G, the source terminal 10S and the drain terminal 10D is not limited. In some embodiments, the gate terminal 10G is a stack structure including first a doped GaN layer, then either a dielectric layer or a piezoelectric layer, and then a metal layer, but the present disclosure is not limited thereto. The source terminal 10S and the drain terminal 10D are made of metals.

The gate terminal 10G is formed between the source terminal 10S and the drain terminal 10D. In some embodiments, the second and third aluminum-containing semiconductive layers 120 and 130 are formed between the gate terminal 10G and the drain terminal 10D. The second and third aluminum-containing semiconductive layers 120 and 130 may be in contact with or separated from the drain terminal 10D. In other embodiments, the second and third aluminum-containing semiconductive layers 120 and 130 are formed between the gate terminal 10G and the source terminal 10S according to a different layout of the photomask M1. The second and third aluminum-containing semiconductive layers 120 and 130 may be in contact with or separated from the source terminal 10S. The gate terminal 10G, the source terminal 10S, and the drain terminal 10D are electrically connected to the first aluminum-containing semiconductive layer 110.

In some embodiments, a band gap discontinuity between the first aluminum-containing semiconductive layer 110 and the second aluminum-containing semiconductive layer 120 creates a 2DEG layer 115 of highly mobile electrons within the first aluminum-containing semiconductive layer 110. The 2DEG layer 115 is formed near a junction of the first aluminum-containing semiconductive layer 110 and the second aluminum-containing semiconductive layer 120. When the semiconductor device 10 is in operation, the 2DEG layer 115 allows charges to flow through the first aluminum-containing semiconductive layer 110. The gate terminal 10G is configured for voltage bias and electrical coupling with the 2DEG layer 115. As this stage, the formation of the semiconductor device 10 is complete. In some embodiments, an on-state resistance of the semiconductor device 10 is substantially less than 1.3 Ω.

For applications of speed switches, an on-state resistance of a power device is important. The AlₓGa₁₋ₓN of a HEMT device is sensitive to electronic result. In the HEMT device of the present disclosure, a thin film of the second aluminum-containing semiconductive layer 120, the fourth aluminum-containing semiconductive layer 140, the fifth aluminum-containing semiconductive layer 150 or the sixth aluminum-containing semiconductive layer 160 is inserted between two thicker aluminum-containing semiconductive layers. An electronic performance of such HEMT device can be improved.

One aspect of the present disclosure provides a semiconductor device. The semiconductor device includes: a substrate; an epitaxial layer on the substrate; a first aluminum-containing semiconductive layer on the epitaxial layer; a source terminal, a drain terminal, and a gate terminal on the first aluminum-containing semiconductive layer, wherein the gate terminal is between the source terminal and the drain terminal; a second aluminum-containing semiconductive layer over the first aluminum-containing semiconductive layer and between the gate terminal and the drain terminal; and a third aluminum-containing semiconductive layer over the second aluminum-containing semiconductive layer. The first aluminum-containing semiconductive layer has a first concentration of aluminum, the second aluminum-containing semiconductive layer has a second concentration of aluminum, and the third aluminum-containing semiconductive layer has a third concentration of aluminum. The second concentration is substantially greater than the first concentration, and the second concentration is substantially greater than the third concentration.

One aspect of the present disclosure provides another semiconductor device. The semiconductor device includes: a first aluminum-containing semiconductive layer; a source structure and a drain structure on the first aluminum-containing semiconductive layer; a gate structure on the first aluminum-containing semiconductive layer and between the source structure and the drain structure; a second aluminum-containing semiconductive layer over the first aluminum-containing semiconductive layer and between the gate structure and the drain structure; a third aluminum-containing semiconductive layer over the second aluminum-containing semiconductive layer and between the gate structure and the source structure; and a fourth aluminum-containing semiconductive layer over the first aluminum-containing semiconductive layer and adjacent to the gate structure. The first aluminum-containing semiconductive layer has a first concentration of aluminum, the second aluminum-containing semiconductive layer has a second concentration of aluminum, and the second concentration is substantially greater than the first concentration.

Another aspect of the present disclosure provides a method for manufacturing a semiconductor device. The method includes: receiving a substrate; epitaxially growing an epitaxial layer on the substrate; depositing a first aluminum-containing semiconductive layer on the epitaxial layer; forming a second aluminum-containing semiconductive layer on the first aluminum-containing semiconductive layer; and forming a third aluminum-containing semiconductive layer on the second aluminum-containing semiconductive layer. A first aluminum composition in a first precursor for forming the first aluminum-containing semiconductive layer is substantially less than a second aluminum composition in a second precursor for forming the second aluminum-containing semiconductive layer.

The foregoing outlines features of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods or steps, presently existing or later to be developed, that perform substantially the same function or achieve substantially the same result as the corresponding embodiments described herein, can be utilized according to the present invention. Accordingly, the appended claims are intended to include within their scope such processes, machines, manufacture, compositions of matter, means, methods and steps.

1. A semiconductor device, comprising:
a substrate;
an epitaxial layer on the substrate;
a first aluminum-containing layer on the epitaxial layer;
a source terminal, a drain terminal, and a gate terminal on the first aluminum-containing layer, wherein the gate terminal is between the source terminal and the drain terminal;
a second aluminum-containing layer over the first aluminum-containing layer and between the gate terminal and the drain terminal; and
a third aluminum-containing layer over the second aluminum-containing semiconductive layer, wherein
the first aluminum-containing layer has a first concentration of aluminum,
the second aluminum-containing layer has a second concentration of aluminum,
the third aluminum-containing layer has a third concentration of aluminum, wherein the second concentration is different from the first concentration and the third concentration.

2. The semiconductor device of claim 1, wherein the first concentration is substantially same as the third concentration.

3. The semiconductor device of claim 1, wherein the epitaxial layer includes gallium nitride and has a thickness between about 0.1 micrometer (μm) and about 20 μm.

4. The semiconductor device of claim 1, wherein the first, second and third aluminum-containing layers respectively include aluminum gallium nitride (AlGaN).

5. The semiconductor device of claim 1, wherein the third aluminum-containing layer covers a portion of the second aluminum-containing layer.

6. The semiconductor device of claim 1, wherein the third aluminum-containing layer covers an entirety of the second aluminum-containing layer.

7. The semiconductor device of claim 1, wherein
the second concentration is substantially greater than the first concentration, and
the second concentration is substantially greater than the third concentration.

8. The semiconductor device of claim 1, wherein
the first aluminum-containing layer has a first band gap,
the second aluminum-containing layer has a second band gap, and
the first band gap is different from the second band gap.

9. The semiconductor device of claim 1, wherein
the first aluminum-containing layer has a first band gap,
the third aluminum-containing layer has a third band gap, and
the first band gap is substantially equal to the third band gap.

10. The semiconductor device of claim 1, wherein
the first aluminum-containing layer has a first thickness,
the second aluminum-containing layer has a second thickness,
the third aluminum-containing layer has a third thickness,
the first thickness is substantially greater than the second thickness, and
the third thickness is substantially greater than the second thickness.

11. The semiconductor device of claim 1, wherein an on-state resistance of the semiconductor device is substantially less than 1.3 ohm (Ω).

12. A semiconductor device, comprising:
a first aluminum-containing layer;
a source structure and a drain structure on the first aluminum-containing layer;
a gate structure on the first aluminum-containing layer and between the source structure and the drain structure;
a second aluminum-containing layer over the first aluminum-containing semiconductive layer and between the gate structure and the drain structure;
a third aluminum-containing layer over the second aluminum-containing layer and between the gate structure and the source structure; and
a fourth aluminum-containing layer over the first aluminum-containing layer and adjacent to the gate structure, wherein
the first aluminum-containing layer has a first concentration of aluminum,
the second aluminum-containing layer has a second concentration of aluminum, and
the second concentration is substantially greater than the first concentration.

13. The semiconductor device of claim 12, wherein the fourth aluminum-containing layer is between the gate structure and the second aluminum-containing layer.

14. The semiconductor device of claim 12, wherein the fourth aluminum-containing layer is between the gate structure and the source structure.

15. The semiconductor device of claim 12, wherein
the third aluminum-containing layer has a third concentration of aluminum,
the fourth aluminum-containing layer has a fourth concentration of aluminum,
the third concentration is substantially equal to the first concentration, and
the fourth concentration is substantially greater than the first concentration.

16. The semiconductor device of claim 15, wherein the fourth concentration is substantially equal to the second concentration.

17. The semiconductor device of claim 15, wherein the fourth concentration is substantially greater than the second concentration.

18. A method for manufacturing a semiconductor device, comprising:
receiving a substrate;
epitaxially growing an epitaxial layer on the substrate;
depositing a first aluminum-containing layer on the epitaxial layer;
forming a second aluminum-containing layer on the first aluminum-containing semiconductive layer; and
forming a third aluminum-containing layer on the second aluminum-containing layer,
wherein a first aluminum composition in a first precursor for forming the first aluminum-containing layer is substantially less than a second aluminum composition in a second precursor for forming the second aluminum-containing layer.

19. The method of claim 18, wherein the first aluminum composition in the first precursor for forming the first aluminum-containing layer is substantially same as a third aluminum composition in a third precursor for forming the third aluminum-containing layer.

20. The method of claim 18, wherein the first aluminum-containing layer, the second aluminum-containing layer and the third aluminum-containing layer are formed by chemical vapor deposition (CVD) operations.
